(19) United States
(12) Patent Application Publication
(10) Pub. No.: US 2021/0175880 A1
(43) Pub. Date: Jun. 10, 2021

(54) COMPARATOR CIRCUIT WITH LOW SUPPLY NOISE

(71) Applicant: NATIONAL CHIAO TUNG UNIVERSITY, HSINCHU CITY (TW)

(72) Inventors: SHIH-HSING WANG, HSINCHU CITY (TW); CHUNG-CHIH HUNG, TAINAN COUNTY (TW)

(21) Appl. No.: 16/785,888

(22) Filed: Feb. 10, 2020

(30) Foreign Application Priority Data
Dec. 5, 2019 (TW) 108144555

(51) Int. Cl. H03K 5/24

(52) U.S. Cl. CPC H03K 5/2472

(57) ABSTRACT

A low supply noise comparison circuit include a first dynamic comparator, a second dynamic comparator and a control circuit. The first dynamic comparator is a pre-amplifier for the second dynamic comparator. The control circuit will activate the second dynamic comparator after the first dynamic comparator is activated for a preset time. So the first and second dynamic comparators will not be activated at the same time and a high supply noise is avoided.

This application claims priority for Taiwan (R.O.C.) patent application no. 108144555 filed on Dec. 5, 2019, the content of which is incorporated by reference in its entirely.

### BACKGROUND OF THE INVENTION

### 1. Field of the Invention

The present invention is related to a comparator circuit, and more particularly to a comparator circuit with low supply noise.

### 2. Description of the Related Art

Comparators are common electronic components, and in some circuit designs, the comparator plays an important role, for example, in an analog to digital converter (ADC), performance of the comparator affects accuracy, speed and power consumption of the ADC. Common types of comparators include static comparator and dynamic comparator. Since the static comparator has static power consumption and dynamic comparator does not, dynamic comparators are more commonly used in various applications. The dynamic comparator uses a positive feedback scheme to obtain a gain G=exp(Δt/τm), that is, the gain increases exponentially over time, so the dynamic comparator can easily have a high value of gain, wherein τm=C/gm is a regeneration time constant, C is a load, and gm is transconductance. Because of not having static power consumption, the dynamic comparator has low power consumption and higher gain compared to the static comparator.

In some applications, in order to achieve a higher gain or reduce an offset voltage of the comparator, multiple comparators are connected in series to form a comparator circuit. For example, “A 70.7-dB SNDR 100-kS/s 14-b SAR ADC with attenuation capacitance calibration in 0.35-μm CMOS”, journal of “Analog Integrated Circuits and Signal Processing” Volume 89, pages 357-371 in 2016, disclosed a comparator circuit using two static comparators, which are connected in series, to form a preamplifier. Although each of the two static comparators have a gain less than 10, the combination of the two static comparators can generate a high gain, for example, when the gain of the static comparator of each stage is 6, the combination of the two static comparators can generate a gain of 36=6×6.

However, when multiple comparators of the comparator circuit are activated at the same time, it causes a high transient current on a power supply terminal and a ground terminal, so higher supply noise occurs on the power supply terminal and the ground terminal, and may be coupled to input terminals of the comparator, and it causes the comparator circuit to make a wrong determination possibly. Therefore, what is needed is to develop a comparator circuit with low supply noise, to solve above-mentioned problems.

### SUMMARY OF THE INVENTION

An objective of the present invention is to provide a comparator circuit with low supply noise.

According to the present invention, a comparator circuit with low supply noise includes a first dynamic comparator, a second dynamic comparator, a first enable switch, a second enable switch and a control circuit. The first dynamic comparator compares a first input signal with a second input signal to generate a first output signal and a second output signal. The second dynamic comparator generates a first comparison signal and a second comparison signal based on the first output signal and the second output signal. The second comparison signal is complementary to the first comparison signal. The first and second enable switches are configured to activate or deactivate the first and second dynamic comparators, respectively. The control circuit is configured to turn on the second enable switch to activate the second dynamic comparator after the first dynamic comparator is activated for a preset time. Therefore, the comparator circuit of the present invention can activate the first and second dynamic comparators at different time points, respectively, so as to reduce supply noise.

In an embodiment, the control circuit can activate the second dynamic comparator when the gain of the first dynamic comparator is equal to or higher than the preset value, so as to prevent the comparator circuit from generating wrong determination.

### BRIEF DESCRIPTION OF THE DRAWINGS

The structure, operating principle and effects of the present invention will be described in detail by way of various embodiments which are illustrated in the accompanying drawings.

FIG. 1 shows a conventional dynamic comparator.

FIG. 2 shows an architecture of the conventional dynamic comparator 10 of FIG. 1.

FIG. 3 shows a two-stage pipelined comparator circuit of the present invention.

FIG. 4 illustrates a method for reducing supply noise, according to the present invention.

FIG. 5 shows an embodiment of a sensing time tracking circuit.

FIG. 6 shows output waveforms of two dynamic comparators of FIG. 3.

FIG. 7 shows waveforms of the signals in FIGS. 3 and 5 in a typical-typical process corner and a slow-slow process corner.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise”, “include” and “have”, and variations such as “comprises”, “comprising”, “includes”, “including”, “has” and “having” will be acknowledged to imply the inclusion of stated elements but not the exclusion of any other elements.

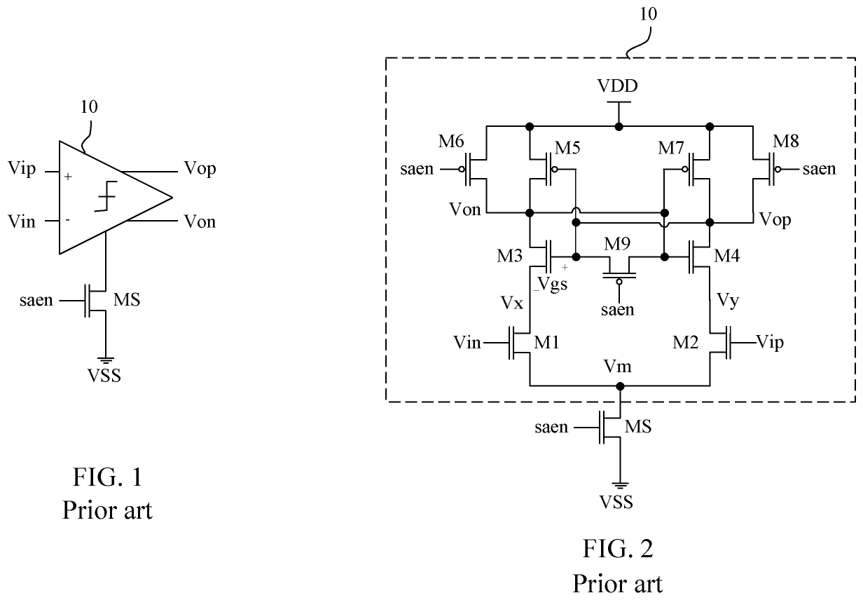

FIG. 1 shows a conventional dynamic comparator 10. The conventional dynamic comparator 10 compares input signals Vip and Vin to generate comparison signals Vop and Von, which are complementary to each other, that is, when the comparison signal Vop is “1”, the comparison signal Von is “0”; in contrast, when the comparison signal Vop is “0”, the comparison signal Von is “1”. The enable switch MS is connected to the dynamic comparator 10, and configured to activate or deactivate the dynamic comparator 10. FIG. 2 shows an embodiment of the dynamic comparator 10 of FIG. 1. When the enable signal saen is “0”, the dynamic comparator 10 is in a reset state, and at this time, the comparison signals Vop and Von are pre-charged to a level of voltage VDD regardless of values of the input signals Vip and Vin. The voltage VDD is a supply voltage of the dynamic comparator. When the enable signal saen is “1”, the enable switch MS is turned on to make Vm=VSS, wherein voltage VSS is a ground voltage of the dynamic comparator; at this time, the differential input pair, which includes transistors M1 and M2, can determine to turn on the transistor M1 or M2 based on values of the input signals Vip and Vin. When Vin>Vip, the transistor M1 is turned on to make a drain voltage Vx of the transistor M1 drop, and after a gate-source voltage of the transistor M3 becomes higher than the threshold voltage Vth1 of the transistor M3 because of drop of the drain voltage Vx, the transistor M3 is turned on to make the comparison signal Von drop, and eventually the comparison signal Von is equal to VSS (that is, Von=VSS) and the comparison signal Vop is equal to VDD (that is, Vop=VDD). In the other hand, when the enable signal saen is “1” and Vin<Vip, the comparison signal Von is equal to VDD (that is, Von=VDD) and the comparison signal Vop is equal to VSS (that is, Vop=VSS). The circuit and operation of the dynamic comparator 10 of FIG. 2 is well known in the art, so detailed descriptions are not repeated herein.

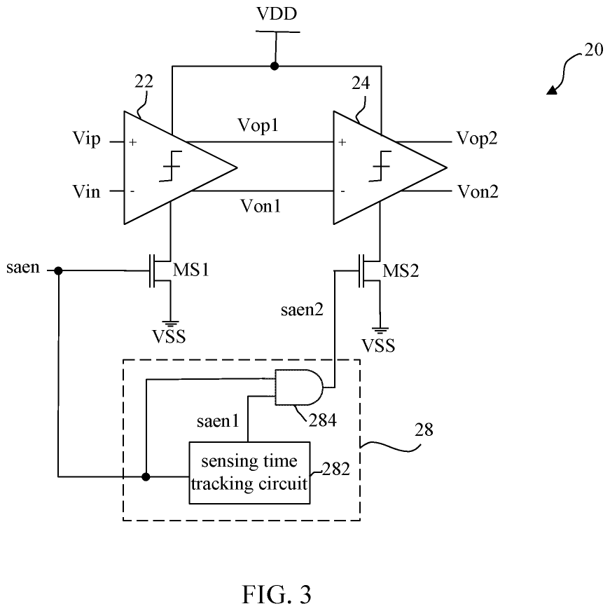

FIG. 3 shows a two-stage pipelined comparator circuit 20 of the present invention. The two-stage pipelined comparator circuit 20 comprises dynamic comparators 22 and 24, enable switches MS1 and MS2, and a control circuit 28. The dynamic comparator 22 compares the input signals Vip and Vin to generate output signals Vop1 and Von1, the dynamic comparator 24 compares the output signals Vop1 and Von1 to generate comparison signals Vop2 and Von2. The dynamic comparator 22 is used as a pre-amplifier, and detailed circuits of the dynamic comparators 22 and 24 can refer to that of the dynamic comparator 10 of FIG. 2. In this embodiment, the comparator circuit 20 has zero static power consumption because of using the dynamic comparators 22 and 24, so that the comparator circuit 20 of the present invention has lower power consumption compared with the conventional technology using static comparators. The enable switches MS1 and MS2 are connected to the dynamic comparators 22 and 24 and configured to activate or deactivate the dynamic comparators 22 and 24, respectively. In an embodiment, each of the enable switches MS1 and MS2 can be, but not limited to, a MOSFET.

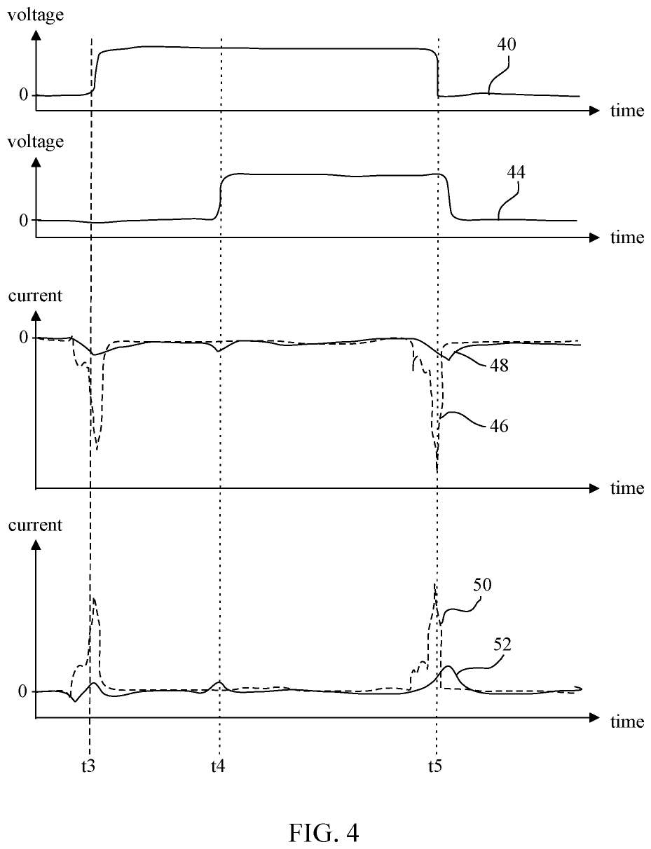

FIG. 4 illustrates a method for reducing supply noise, according to the present invention. As shown in FIG. 4, a waveform 40 is the enable signal saen, a waveform 44 is an enable signal saen2, and waveforms 46 to 52 show occurrence of supply noise. As shown in FIG. 3, since the dynamic comparators 22 and 24 are connected to the same power terminal (VDD) and the same ground terminal (VSS), when the dynamic comparators 22 and 24 are activated or deactivated at the same time, high transient current occurs on the power terminal, and it causes higher supply noise on the power terminal, as shown in parts of the waveform 46 at time points t3 and t5; similarly, high transient current flowing to ground terminal also occurs, and it causes higher supply noise on the ground terminal, as shown in parts of the waveform 50 at time points t3 and t5. The supply noise can be coupled to the input terminals of the dynamic comparators 22 and 24, to cause the dynamic comparator to make wrong determination. The comparator circuit 20 of the present invention can use the control circuit 28 to control the dynamic comparator 24 to activate after the dynamic comparator 22 is activated for a preset time, as shown in a part of the waveform 40 at time point t3 and a part of the waveform 44 at time point t4; furthermore, the dynamic comparators 22 and 24 are not activated at the same time, so that supply noise can be reduced, as shown in parts of the waveforms 48 and 52 at time points t3 and t4. Compared with the condition that the dynamic comparators 22 and 24 are activated at the same time, the method of activating the dynamic comparators 22 and 24 separately according to the present invention can reduce 85% of supply noise. At the time point t5, the enable signal saen is changed to low level to deactivate the dynamic comparator 22; because of being delayed by the logic gate 284, the enable signal saen2 is changed to low level after a delay time of a logic gate after the enable signal saen is changed to low level, so as to prevent the dynamic comparators 22 and 24 from being deactivated at the same time, thereby reducing supply noise.

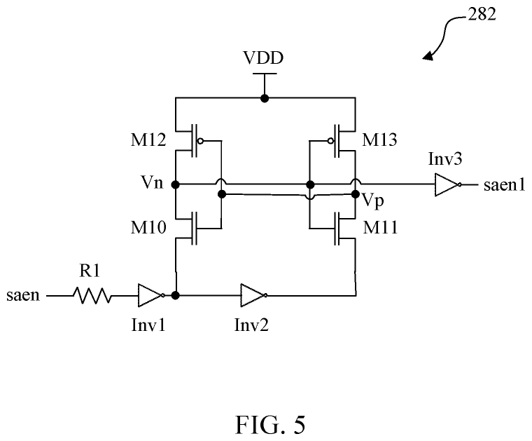

The control circuit 28 of FIG. 3 comprises a sensing time tracking circuit 282 and an AND gate 284. The sensing time tracking circuit 282 can receive and delay the enable signal saen to generate the enable signal saen1, and the AND gate 284 has two input terminals for receiving the enable signals saen and saen1, and can generate the enable signal saen2 to turn on or off the enable switch MS2 based on the enable signals saen and saen1. The control circuit 28 shown in FIG. 3 is merely an exemplary embodiment of the present invention, and the architecture of the control circuit 28 of the present invention is not limited to above-mentioned example. FIG. 5 shows an embodiment of the sensing time tracking circuit 282. As shown in FIG. 5, an inverter Inv1 can receive the enable signal saen, an input terminal of an inverter Inv2 is connected to an output terminal of the inverter Inv1, and control terminals of the transistors M10 and M12 are connected to each other, two terminals of the transistor M10 are connected to an output terminal of the inverter Inv1 and a terminal of the transistor M12, respectively, the other terminal of the transistor M12 receives the supply voltage VDD, control terminals of the transistors M11 and M13 are connected to each other and also connected to the terminal of the transistor M12, two terminals of the transistor M11 are connected to the output terminal of the inverter Inv2 and a terminal of the transistor M13, respectively, the other terminal of the transistor M13 receives the supply voltage VDD. The inverter Inv3 has an input terminal connected to the terminal of the transistor M12, and an output terminal for providing the enable signal saen1.

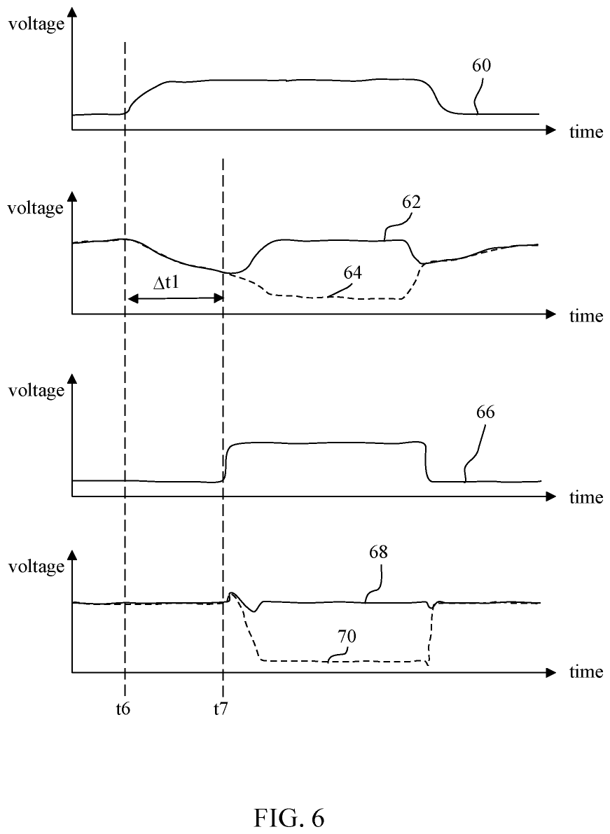

Furthermore, the gain G=exp(Δt/τm) of the dynamic comparator is increased over time, so when the dynamic comparator 24 is activated after a preset time after the dynamic comparator 22 is activated, the dynamic comparator 24 can be prevented from being activated under a condition that the gain of the dynamic comparator 22 is insufficient, so as to prevent wrong determination of the dynamic comparator 24. FIG. 6 shows outputs of the two dynamic comparators of FIG. 3. As shown in FIG. 6, a waveform 60 is a voltage on the control terminal of the enable switch MS1, a waveform 62 is the output signal Vop1 of the dynamic comparator 22, a waveform 64 is the output signal Von1 of the dynamic comparator 22, a waveform 66 is the enable signal saen2, a waveform 68 is the comparison signal Vop2 of the dynamic comparator 24, and a waveform 70 is the output signal Von2 of the dynamic comparator 24. The gain G1=exp(Δt1/τm1) of the first stage (the dynamic comparator 22) can be determined based on the preset time Δt1. Δt the time point t6, the dynamic comparator 22 is activated, the inputted small signals Vip and Vin are amplified by the dynamic comparator 22, and after the sensing time tracking circuit 282 tracks for the preset time Δt1, the dynamic comparator 24 is activated at the time point t7, as shown in the waveforms 66, 68 and 70. According to the present invention, the dynamic comparator 24 is not activated until the gain G1 of the dynamic comparator 22 is equal to or higher than a preset value, so as to prevent wrong determination. Since the dynamic comparator 24 has a higher regeneration time constant τm2, the gain G2 of the dynamic comparator 24 can reach a preset value after the dynamic comparator 24 is activated, and the comparison signals Vop2 and Von2 can quickly reach a high level state or a low level state.

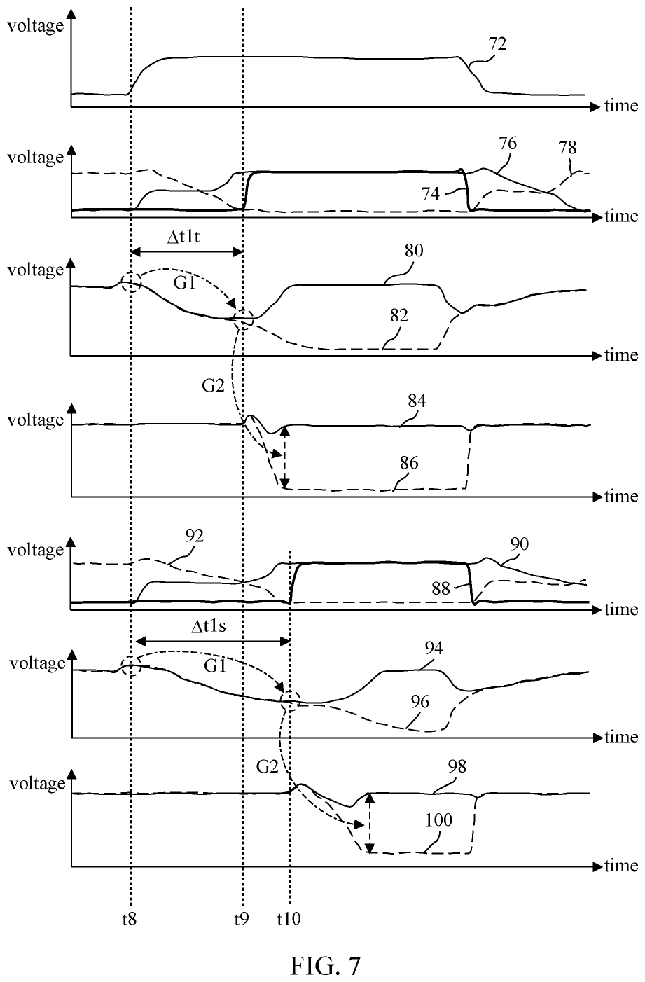

The regeneration time constant τm1 of the dynamic comparator 22 can be preset as a fixed value, so that the control circuit 28 can be used to adjust the time Δt1 to control the gain G1 after the dynamic comparator 24 is activated. Furthermore, the sensing time tracking circuit 282 can have transistors with sizes respectively the same as that of the transistors of the dynamic comparator 22, or have a regeneration time constant the same as the regeneration time constant τm1 of the dynamic comparator 22, so that the sensing time tracking circuit 282 can activate the dynamic comparator 24 only after the gain G1 of the dynamic comparator 22 reaches the preset value in different process corner. FIG. 7 shows waveforms of the signals in FIGS. 3 and 5 in a typical-typical process corner and a slow-slow process corner. As shown in FIG. 7, a waveform 72 is the enable signal saen, waveforms 74 and 88 are the enable signal saen2, waveforms 76 and 90 are a voltage on a node Vp, waveforms 78 and 92 are a voltage on a node Vn, waveforms 80 and 94 are the output signal Vop1, waveforms 82 and 96 are the output signal Von1, waveforms 84 and 98 are the comparison signal Vop2, and waveforms 86 and 100 are the comparison signal Von2. The waveforms 74 to 86 are the signal waveforms corresponding to the typical-typical process corner, and the waveforms 88 to 100 are the signal waveforms corresponding to slow-slow process corner. When the dynamic comparator 22 is activated and operates in the typical-typical process corner, as shown in waveform 72 and the time point t8, the sensing time tracking circuit 282 will activate the dynamic comparator 24 after a time Δt1t, and it makes the gain G1 of the dynamic comparator 22 reach 105 during the time Δt1t, as shown in waveform 74 and the time point t9. Because of the sensing time tracking circuit 282, the comparator circuit 20 can track the designed gain of the first stage (dynamic comparator 22) under the typical-typical process corner. When the dynamic comparator 22 is activated and operates in the slow-slow process corner, the sensing time tracking circuit 282 will activate the dynamic comparator 24 after a time Δt1s, and it makes the gain G1 of the dynamic comparator 22 reach 75 during the time Δt1s, as shown in waveform 88 and the time point t10. Because of the sensing time tracking circuit 282, the comparator circuit 20 can track the designed gain of the first stage under the slow-slow process corner. The comparator circuit 20 can also track the designed gain of the first stage under different process corner conditions.

The present invention disclosed herein has been described by means of specific embodiments. However, numerous modifications, variations and enhancements can be made thereto by those skilled in the art without departing from the spirit and scope of the disclosure set forth in the claims.

1. A comparator circuit with low supply noise, applied to compare a first input signal and a second input signal to generate a first comparison signal and a second comparison signal, the second comparison signal being complementary to the first comparison signal, and the comparator circuit comprising:
a first dynamic comparator configured to compare the first input signal with the second input signal to generate a first output signal and a second output signal;
a second dynamic comparator connected to the first dynamic comparator, and configured to generate the first comparison signal and the second comparison signal based on the first output signal and the second output signal;
a first enable switch connected to the first dynamic comparator and configured to activate or deactivate the first dynamic comparator;
a second enable switch connected to the second dynamic comparator, configured to activate or deactivate the second dynamic comparator;
a control circuit connected to a control terminal of the second enable switch, and configured to turn on the second enable switch to activate the second dynamic comparator after the first dynamic comparator is activated for a preset time.

2. The comparator circuit according to claim 1, wherein after the first dynamic comparator is activated for the preset time, a gain of the first dynamic comparator is equal to or higher than a preset value.

3. The comparator circuit according to claim 1, wherein the control circuit comprises:
a sensing time tracking circuit configured to delay a first enable signal to generate a second enable signal, wherein the first enable signal is used to turn on or off the first enable switch; and
an AND gate connected to the sensing time tracking circuit and the second enable switch and having two input terminals configured to receive the first enable signal and the second enable signal, respectively, and an output terminal configured to provide a third enable signal to turn on or off the second enable switch.

4. The comparator circuit according to claim 3, wherein the sensing time tracking circuit comprises transistors with sizes respectively the same as that of transistors of the first dynamic comparator.

5. The comparator circuit according to claim 3, wherein the sensing time tracking circuit has a first regeneration time constant equivalent to a second regeneration time constant of the first dynamic comparator.

6. The comparator circuit according to claim 3, wherein the sensing time tracking circuit comprises:
a first inverter having a first input terminal and a first output terminal, wherein the first input terminal is configured to receive the first enable signal;
a second inverter having a second input terminal and a second output terminal, wherein the second input terminal is connected to the first output terminal;
a first transistor having a first terminal, a second terminal, and a first control terminal, wherein the first terminal is configured to receive a supply voltage;
a second transistor having a third terminal, a fourth terminal, and a second control terminal, wherein the third terminal is connected to the second terminal, the fourth terminal is connected to the first output terminal, and the second control terminal is connected to the first control terminal;
a third transistor having a fifth terminal, a sixth terminal, and a third control terminal, wherein the fifth terminal configured to receive the supply voltage, the sixth terminal is connected to the first control terminal, the third control terminal is connected to the second terminal;
a fourth transistor having a seventh terminal, an eighth terminal, and a fourth control terminal, wherein the seventh terminal is connected to the sixth terminal, the eighth terminal is connected to the second output terminal, and the fourth control terminal is connected to the second terminal; and
a third inverter having a third input terminal and a third output terminal, wherein the third input terminal is connected to the second terminal, and the third output terminal is configured to provide a second enable signal.
